(19) United States
(12) Patent Application Publication
(10) Pub. No.: US 2006/0037536 A1
(43) Pub. Date: Feb. 23, 2006

(54) Plasma resistant member, manufacturing method for the same and method of forming a thermal spray coat

(75) Inventors: Yoshio Kobayashi, Kanagawa (JP); Masahiko Ichishima, Aichi (JP); Yuu Yokoyama, Kanagawa (JP)

Correspondence Address: FOLEY AND LARDNER LLP;SUITE 500, 3000 K STREET NW, WASHINGTON, DC, 20007, US

(73) Assignee: TOSHIBA CERAMICS CO., LTD.

(21) Appl. No.: 10/964,650

(22) Filed: Oct. 15, 2004

(30) Foreign Application Priority Data
Oct. 24, 2003 (JP) 2003-363967
Jan. 16, 2004 (JP) 2004-008659
Apr. 14, 2004 (JP) 2004-118666

(51) Int. Cl. B32B 9/00; B32B 19/00; C23C 16/00; B44C 1/22

(52) U.S. Cl. 118/715; 428/701; 428/702; 427/446; 156/345.1; 216/83

(57) ABSTRACT

The present invention concerns a plasma resistant member comprising Y₂O₃ or YAG thermal performed thermal spray on an alumina base material, wherein the surface roughness Ra of the alumina base material is 5 μm or more and 15 μm or less. By rendering the surface layer of the alumina base material porous to a porosity of 20% or more and 60% or less to a depth of ranging from 10 μm to 1O0 μm, aplasma resistant member having an enhanced adhesion strength can be provided. The aforementioned plasma resistant member can be produced by subjecting the surface of analumina base material to chemical etching, and then performing thermal spray Y₂O₃ or YAG on the roughened surface of the alumina base material to form a plasma resistant layer.

The present invention claims foreign priority to Japanese patent application No. JP.2003-363967 filed in the Japanese Patent Office on Oct. 24, 2003, JP.2004-008659 filed in the Japanese Patent Office on Jan. 16, 2004 and JP.2004-118666 filed in the Japanese Patent Office on Apr. 4, 2004 the contents of which are incorporated herein by reference.

### BACKGROUND OF THE INVENTION

1. Field of the Invention

The present invention relates to a plasma resistant member made of ceramic material and a manufacturing method for the same, and more particularly to a plasma resistant member having a ceramic surface mainly composed of Y₂O₃or YAG (yttrium aluminum garnet: Y₃Al₅O₁₂) which is suitable for use in semiconductor producing apparatus and a process for the production thereof.

2. Description of the Related Art

Fine processing steps in manufacturing processes for producing semiconductor devices generally has deposition processes such as PVD ard CVD, or etching processes using corrosive gases. A proportion of these steps in the manufacturing processes tends to increase with the enhancement of fineness and complexity of work of semiconductor devices. Since the aforementioned deposition and etching processes are conducted under severe conditions, i.e., in a plasma atmosphere or at a high temperature, a corrosive resistant ceramic material is used to form the treatment vessel to be exposed to the plasma.

In the producing apparatus which realizes the aforementioned steps, a chlorine-based gas such as carbon tetrachloride (CCl₄) and boron chloride (BCl₃) or a fluorine-based gas such as carbon fluoride (CF₄, C₄F₈), nitrogen fluoride (NF₃) and sulfur fluoride (SF₆) is used as an etching gas in, e.g., etching device. Thus, constituent members to be exposed to the plasma in the corrosive gas atmosphere, e.g., an inner wall of an etching chamber, are required a plasma resistant property.

As one of the aforementioned constituent members required to the plasma resistant property, there is known a sintered ceramic material mainly composed of a compound containing at least one element selected from groups 2A and 3A in the periodic table and having a surface roughness Ra of 1 μm or less and a porosity of 3% or less (see Japanese Patent Unexamined Publication JP-A-10-45461). Further, the sintered ceramic material has been proposed which is formed by a sintered yttrium-aluminum garnet material having a porosity of 3% or less on the surface thereof to be exposed to the plasma and has a surface roughness Ra (arithmetic mean deviation of the profile) of 1 μm or less (see Japanese Patent Unexamined Publication JP-A-10-236871).

These plasma resistant ceramics are expensive and thus reduction of cost is desired. Thus, the recent trend is to use a technique for forming a plasma resistant ceramic from alumina ceramic, which are inexpensive. In some detail, an attempt has been made to form a plasma resistant material layer on the surface of an inexpensive alumina base material. In this technique, however, the adhesion strength between the base material made of alumina ceramic and the plasma resistant surface layer is important. Accordingly, when the adhesion strength between these materials is poor, the plasma resistant surface layer can be exfoliated from the alumina base material during the use of the plasma resistant member, causing the occurrence of defective products at the semiconductor production process.

In an attempt to eliminate these difficulties, it has been practiced to subject the surface of the alumina ceramic base material to sandblasting for the purpose of enhancing the adhesion strength thereof. However, the aforementioned roughening method involving sandblasting cannot provide a sufficient anchoring effect. Therefore, there are some problems of spray coat exfoliation. In other words, because the base material is a ceramic which is a brittle material, the surface roughened by the aforementioned roughening method has a profile that widens outward which forms V-shaped section. Further, since the roughened structure depends on the crystal particle diameter, the upper limit of the surface roughness Ra is 5 μm. Accordingly, the resulting anchoring effect, if any, is insufficient. Thus, a thermal spray layer having higher adhesion strength has been desired. Further, the surface of the base material of the alumina ceramic which has been damaged by blasting so much as to be ready to fall can be exfoliated together with the thermal spray coating in accordance with the change of temperature during using it. Therefore, the sandblasting method is disadvantageous in that the surface of the ceramic member itself can cause contamination by particles.

Further, because the formation of the roughened surface on the ceramic material is accompanied by the occurrence of microcracks on the surface of the ceramic material, when thermal spray coat is formed on the ceramic material having these microcracks, a sufficient anchoring effect cannot be exerted. These microcracks possibly act as starting points that cause exfoliation of thermal spray coat. Some materials having a remarkably high strength, such as quartz, have a possibility of breaking the base material due to the microcracks. The thermal spray coat is given stresses developed by heat hysteresis or like. Accordingly, when the adhesion strength between the base material and the thermal spray coat is too small, the thermal spray coat can be exfoliated and thus cannot act as a protective layer. Further, serious problems such as generation of particles can arise.

### SUMMARY OF THE INVENTION

The present invention has been worked out under these circumstances. An object of the present invention is to provide a plasma resistant member having a plasma resistant coating layer with high adhesion strength on the surface thereof and a manufacturing method for the same. Another object of the present invention is to provide a method for forming a protective layer and a manufacturing method for a composite material, both of methods are capable of preventing an occurrence of microcracks on the surface of the ceramic material and also preventing the exfoliation of plasma resistant protective layer, when forming a protective layer having a plasma resistant layer on a brittle material such as a ceramic by a thermal spray.

According to a first aspect of the present invention, there is provided a plasma resistant member, comprising:

a base material made of alumina; and

a thermal spray layer made of Y₂O₃ or YAG formed on a surface of the base material,

wherein at least apart of the surface of the base material on which the thermal spray layer is formed has a surface roughness Ra ranging from 5 μm to 15 μm.

According to a second aspect of the present invention, there is provided a plasma resistant member, comprising:

a base material made of alumina; and

a thermal spray layer made of Y₂O₃ or YAG formed on a surface layer of the base material,

wherein at least a part of the surface layer of the base material is a porous layer having a porosity ratio of 20% or more and 60% or less with a depth thereof being 10 μm or more and 100 μm or less.

According to a third aspect of the present invention according to the second aspect of the present invention, at least a part of the surface layer on which the thermal spray layer is formed has a surface roughness Ra ranging from 2 μm to 10 μm.

According to a fourth aspect of the present invention according to the first aspect of the present invention, the thermal spray layer comprises Y₂O₃ including Si ranging from 100 ppm to 1000 ppm.

According to a fifth aspect of the present invention according to the second aspect of the present invention, the thermal spray layer comprises Y₂O₃ including Si ranging from 100 ppm to 1000 ppm.

According to a sixth aspect of the present invention according to the first aspect of the present invention, at least a surface layer of the base material on which the thermal spray layer is formed has an aspect ratio ranging from 0.3 to 1.0.

According to a seventh aspect of the present invention according to the second aspect of the present invention, at least the surface layer of the base material on which the thermal spray layer is Formed has an aspect ratio ranging from 0.3 to 1.0.

According to an eighth aspect of the present invention, there is provided a method for manufacturing a plasma resistant member, comprising steps of:

performing a chemical etching on a surface of a base material made of alumina, and

performing thermal spray Y₂O₃ or YAG onto the surface of the base material to form a plasma resistant layer.

According to a ninth aspect of the present invention according to the eighth aspect of the present invention, the chemical etching is performed with an acid etching solution at a temperature ranging from 160° C. to 240° C. in a pressure ranging from 0.6 MPa to 3.3 MPa for 3 hours or more and 10 hours or less.

According to a tenth aspect of the present invention according to the eighth aspect of the present invention, the chemical etching is performed with an acid etching solution at a temperature ranging from 180° C. to 240° C. in a pressure ranging from 1.0 MPa to 3.3 MPa for 3 hours or more and 10 hours or less.

According to an eleventh aspect of the present invention according to the ninth aspect of the present invention, the method for manufacturing the plasma resistant member further comprising a step of:

annealing the base material at a temperature ranging from 1,500° C. to 1,800° C. in an atmosphere for 4 hours or more and 8 hours or less after performing the chemical etching.

According to a twelfth aspect of the present invention according to the eleventh aspect of the present invention, at least a surface layer of the base material on which the thermal spray is performed has an aspect ratio ranging from 0.3 to 1.0 after annealing.

According to a thirteenth aspect of the present invention according to the sixth aspect of the present invention, the plasma resistant layer is made of the Y₂O₃, the Y₂O₃ contains Si in an amount of 100 ppm or more and 1000 ppm or less.

According to a fourteenth aspect of the present invention according to the eighth aspect of the present invention, the surface of the base material has a surface roughness Ra ranging from 5 μm to 15 μm after performing the chemical etching.

According to a fifteenth aspect of the present invention according to the eighth aspect of the present invention, a surface layer of the base material is a porous layer having a porosity ratio of 20% or more and 60% or less, and a depth of the porous layer is 10 μm or more and 100 μm or less.

According to a sixteenth aspect of the present invention, there is provided a method for forming a thermal spray coat, comprising steps of:

chemically roughening a surface of a brittle material; and

forming the thermal spray coat by performing thermal spray on the surface of the brittle material,

wherein the roughened surface of the brittle material has a surface roughness Ra of 1 μm or more and 10 or less.

According to a seventeenth aspect of the present invention according to the sixteenth aspect of the present invention, the brittle material is a sintered ceramic material containing crystals having a grain size of 2 μm or more and 70 μm or less, and

the chemical roughening is performed with an acid etching solution.

According to an eighteenth aspect of the present invention according to the sixteenth aspect of the present invention, the brittle material is quartz, and

the chemical roughening is performed by chemical frosting treatment.

According to a nineteenth aspect of the present invention, there is provided a method for manufacturing a composite material comprising a brittle material and a protective coat formed on a surface of the brittle material, comprises steps of:

chemically roughening the surface of the brittle material to obtain a surface roughness thereof ranging from 1 μm to 10 μm; and

performing thermal spray on the surface of the brittle material to form the protective coat.

Note that the surface roughness Ra means an arithmetic mean deviation of the profile.

Note that the aspect ratio is defined as below equation.

$$Aspect ratio = \frac{Rc}{Rsm / 2} \qquad ( Equation 1 )$$

Wherein Rc represents an average height of mounts and valleys in a roughness curve, and Rsm represents an average interval of the each mounts and valleys as shown in FIGS. 1A to 1C.

### BRIEF DESCRIPTION OF THE DRAWINGS

FIG. 1A is a diagram illustrating the calculation of average height of roughness curve elements;

FIG. 1B is a diagram illustrating the calculation of average length of roughness curve elements; and

FIG. 1C is a diagram illustrating the calculation of aspect ratio of the present invention.

FIG. 2A is a first schematic diagram of the measuring instrument for stud pull method for measuring the adhesion force of thermal spray layer.

FIG. 2B is a second schematic diagram of the measuring instrument for stud pull method for measuring the adhesion force of thermal spray layer.

### DETAILED DESCRIPTION OF THE PREFERRED EMBODIMENTS

### First Embodiment

(Plasma Resistant Member)

A first embodiment of implementation of the present invention will be described hereinafter. In the plasma resistant member according to the present embodiment, the surface roughness Ra of the alumina base material is ranging from 5 μm to 15 μm, and a surface layer made of Y₂O₃ or YAG is formed on the roughened surface of the alumina base material, whereby the plasma resistance thereof can be improved. In the present embodiment of implementation of the present invention, the surface roughness Ra of the alumina base material falls within the above defined range, making it possible to predetermine the adhesion strength between the surface of the alumina base material and the surface layer of the plasma resistant member to 8 MPa or more. Whenever the surface roughness Ra of the alumina base material falls outside the above defined range, the adhesion strength between the surface of the alumina base material and the surface layer of the plasma resistant member becomes lower.

In performing thermal spray Y₂O₃ material on the alumina base material to form a plasma resistant layer, it is preferred that the Y₂O₃ material have silicon incorporated therein in an amount of 100 ppm or more and 1,000 ppm or less. Accordingly, the melting point of the Y₂O₃ material is lowered to facilitate thermal spray, making it possible to obtain a uniform thermal spray layer. When the silicon content falls below the above defined range, the desired effect of lowering the melting point of the Y₂O₃ material cannot be expected. On the contrary, when the silicon content exceeds the above defined range, it is likely that the content of a large amount of silicon can cause the production of a second phase and hence an uneven structure.

In the plasma resistant member according to the present embodiment of implementation of the present invention, the alumina as a base material is preferably highly dense and high purity alumina, more preferably having a purity of 99.5% or more. When the purity of the alumina base material falls below the above defined range, the resulting alumina base material is porous up to the interior thereof to disadvantage from the standpoint of strength. The components other than aluminum oxide incorporated in the alumina base material are materials which are unavoidably incorporated in the alumina material during the process for the production of alumina, e.g., Mg, Na, and K.

The thickness of the surface layer made of Y₂O₃ or YAG is preferably 50 μm or more and 500 μm or less. When the thickness of the surface layer falls below the above defined range, the resulting base material exhibits an insufficient plasma resistance and hence a reduced its lifetime to disadvantage. On the contrary, when the surface layer made of Y₂O₃ or YAG is formed to a thickness exceeding the above defined range, the ratio of the material layer having high cost is merely raised. Even in this arrangement, the desired effect of prolonging the lifetime and other effects cannot be expected to disadvantage from the economical standpoint of view. Further, the resulting difference in thermal expansion coefficient causes the rise of heat stress, making it more likely that the thermal spray can be exfoliated.

While the aforementioned embodiment of implementation of the present invention has been described with reference to the case where a surface layer made of Y₂O₃ or YAG is formed on the surface of the alumina base material, an interlayer having intermediate characteristics between the alumina base material and the surface layer made of Y₂O₃ or YAG may be formed interposed therebetween. In some detail, when a layer made of ______ or the like having an intermediate thermal expansion coefficient between that of the two layers is formed, the occurrence of exfoliation due to the difference in thermal expansion coefficient between the alumina base material. Then the surface layer made of Y₂O₃ or YAG can be prevented even if the plasma resistant member is exposed to high temperatures to advantage. The thickness of the interlayer is preferably 50 μm or more and 200 μm or less. When the thickness of the interlayer falls below the above defined range, the desired effect of the interlayer cannot be sufficiently exerted. On the contrary, when the thickness of the interlayer exceeds the above defined range, the improving effect corresponding to the rise of the number of steps required to form the interlayer cannot be expected. Thus, the rise of the thickness of the interlayer is merely uneconomical. The interlayer, too, needs to have a surface roughness Ra 5 μm or more and 15 μm or less as in the case of alumina base material.

(Process for the Production of Plasma Resistant Member)

The plasma resistant member according to the present embodiment can be produced by roughening the surface of an alumina base material, and then forming a surface layer made of Y₂O₃ or YAG on the roughened surface of the alumina base material.

The roughening of the surface of the alumina base material can be accomplished by chemical etching involving the dipping of the alumina base material in an acid etching solution. As the acid etching solution to be used in the chemical etching there may be used an aqueous solution containing sulfuric acid or phosphoric acid. The concentration of the aqueous solution of sulfuric acid to be used herein is preferably 10 mol/l or more and 50 mol/l or less. The concentration of the aqueous solution of phosphoric acid to be used herein is preferably 20 mol/l or more and 60 mol/l or less. When the concentration of the aqueous solution of sulfuric acid or phosphoric acid falls below the above defined range, the resulting etching rate is reduced, causing the drop of working efficiency. On the contrary, when the concentration of the aqueous solution of sulfuric acid or phosphoric acid exceeds the above defined range, the resulting etching rate is too high to fairly control the reaction.

During the chemical etching, the aforementioned acid etching solution is heated. The heating temperature is preferably 160° C. or more and 240° C. or less. When the heating temperature falls below the above defined range, the time required for chemical etching is prolonged, causing the drop of working efficiency on the contrary, when the heating temperature exceeds the above defined range, the resulting etching rate is too high to fairly control the reaction.

During the etching step, the etching solution is preferably given a pressure of 0.6 MPa or more and 3.3 MPa or less. In this manner, the etching rate can be raised.

The etching time is preferably from 3 hours to 10 hours. When the etching time falls below the above defined range, the resulting roughened base material cannot be provided with a sufficiently raised roughness Ra and thus cannot be given an enhanced adhesion strength to thermal spray layer. On the contrary, when the etching time exceeds the above defined range, the alumina base material undergoes deterioration itself and hence drop of strength causing the generation of particles.

The alumina base material may be previously subjected to sandblasting before performing chemical etching. As the sandblasting method there may be used a method commonly used to roughen the surface of ceramic base material, e.g., method which comprises blowing finely divided particles of alumina, silicon carbide or the like having a size of from several micrometers to several millimeters against the surface of the ceramic base material using compressed air. In this manner, the surface layer made of alumina base material is provided with a roughness Ra of about 4.7 μm.

Subsequently, a surface layer made of Y₂O₃ or YAG is formed on the roughened surface of the alumina base material thus obtained.

As the method for forming a surface layer made of Y₂O₃ or YAG on the surface of the alumina base material there may be proposed a method which comprises laminating a sheet-like material of surface layer material such as Y₂O₃ and YAG on the surface of a tabular or block-shaped alumina material, and then sintering the laminate, or a method which comprises thermal spraying a surface layer material comprising Y₂O₃ or YAG onto the surface of a sintered alumina to form a coat layer. Among these methods, the spray spraying method is favorable from the standpoint of working efficiency, adhesion strength, etc.

In the case where Y₂O₃ is used as thermal spray to be formed on the surface layer, Y₂O₃ preferably contains silicon in an amount of 100 ppm or more and 1,000 ppm or less. In this arrangement, the melting point of Y₂O₃ can be lowered to facilitate thermal spray, making it possible to obtain a uniform spray layer.

According to the present embodiment, the surface of the alumina base material is subjected to chemical etching. In this manner, the adhesion strength between the alumina base material and the surface layer made of Y₂O₃ or YAG can be drastically enhanced as compared with the case where the surface of the alumina base material is merely subjected to sandblasting. Thus, in the semiconductor manufacturing apparatus comprising the aforementioned plasma resistant member, the occurrence of contamination by particles can be remarkably prevented.

According to the production process of the present embodiment, the surface roughness Ra can be controlled to a range from 5 μm to 15 μm not only for high purity alumina but also for general-purpose alumina which can be difficultly roughened. In this manner, the alumina base material can be provided with an adhesion strength of 8 MPa or more. In particular, the surface roughness Ra is preferably 7 μm or more and 12 μm or less. When the surface roughness falls within this range, the alumina base material can be provided with an adhesion strength of 12 MPa or more.

### Second Embodiment

While the first embodiment has been described with reference to the case where the surface of an alumina base material is subjected to chemical etching or the like under relatively mild conditions to enhance the adhesion strength between the alumina base material and the surface layer made of Y₂O₃ or YAG, the surface of the alumina base material can be subjected to sandblasting or chemical etching under stronger conditions to render the alumina base material porous itself, making it possible to further enhance the adhesion strength between the two layers without raising the surface roughness thereof.

In some detail, the plasma resistant member according to the present embodiment is obtained by performing thermal spray Y₂O₃ or YAG onto an alumina base material. By using a porous surface layer of the alumina base material, which has a porosity of 20% or more and 60% or less to a depth ranging from 10 μm to 100 μm, it can enhance adhesion strength of the plasma resistant member.

In the present embodiment, when the porosity and the depth of the porous layer fall outside the above defined range, the resulting plasma resistant member exhibits deteriorated adhesion strength to disadvantage. The surface roughness Ra of the plasma resistant member is preferably 2 μm or more and 10μm or less. When the surface roughness of the plasma resistant member falls within the above defined range, the resulting plasma resistant member exhibits a more enhanced adhesion strength.

(Process for the Production of Plasma Resistant Member)

The plasma resistant member according to the present embodiment can be produced by subjecting the alumina base material to chemical etching under severe conditions in respect to the first embodiment as follows.

Referring to preferred etching conditions, the alumina base material can be treated with an acid etching solution having a temperature of 180° C. or more and 240° C. or less at a pressure of 1.0 MPa or more and 3.3 M?a or less for 3 hours or more and 10 hours or less.

The alumina base material which has been subjected to etching is preferably then subjected to annealing at a temperature of 1,500° C. or more and 1,800° C. or less for 4 hours or longer and 8 hours or shorter. When subjected to annealing, the alumina base material can have etched particles firmly bonded to each other, making it possible to prevent the falling of alumina particles. This annealing may be effected also in the first embodiment.

### EXAMPLE

### Examples 1 to 4

Analumina ceramic plate having a purity of 99.5% by weight, a bulk density of 3.97 g/cm³ and a mean particle diameter of 20 μm was prepared. The alumina ceramic plate thus prepared had a surface roughness Ra of 0.8 μm. The surface of the alumina ceramic plate was then subjected to sandblasting with an alumina abrasive #36. #36 is a expression of JIS standard, #36 means a mean particle diameter of the abrasive is about 0.7 mm). As a result, an alumina ceramic plate having a surface roughness Ra of 9.7 μm was obtained. Subsequently, an aqueous solution of sulfuric acid having a concentration of 25% by weight was prepared as an etching solution. The acid etching solution was then adjusted to the temperature set forth in Table 1 below. The aforementioned alumina ceramic plate was then dipped in the acid etching solution for the period of time set forth in Table 1 below to undergo chemical etching so that the alumina ceramic plate was given a roughened surface structure including fine pores. During this etching step, the acid etching solution was given a pressure set forth in Table 1 below. As a result, an alumina ceramic plate having a surface roughness Ra and an aspect ratio set forth in Table 1 was obtained.

Subsequently, thermal spray layer was made on the roughened surface of the alumina ceramic plate to form a Y₂O₃ layer to a thickness of 250 μm.

An adhesion force between the alumina ceramic plate and the thermal spray layer was then measured by a stud pull method. The measurements were then averaged. The results are set forth in Table 1 below. In the stud pull method, a stud pin having a bottom surface area of 5.7 mm² is bonded to the surface of a brittle material having a protective layer formed on the surface thereof with an epoxy resin. The force by which the protective layer is exfoliated off the brittle material when the stud pin is then pulled upward is then measured to determine the adhesion force.

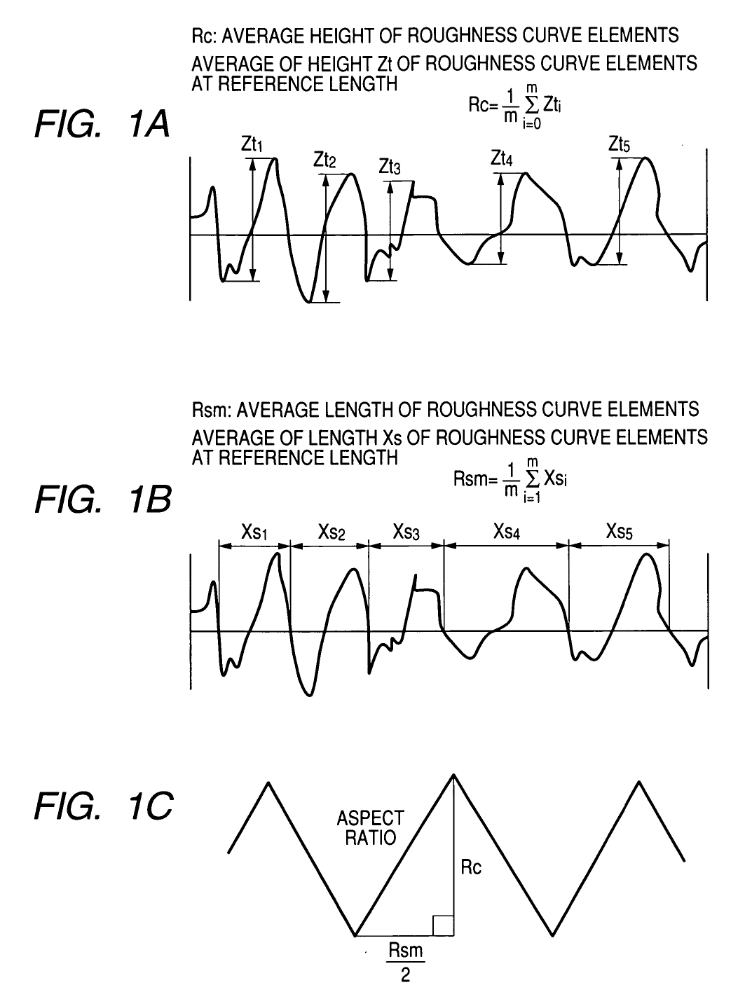

The aspect ratio of the surface of the base material can be calculated from the average height of roughness curve elements and the average length of roughness curve elements by the following equation 1 as shown in FIGS. 1A to 1C.

$$Aspect ratio = \frac{Rc}{Rsm / 2} \qquad ( equation 1 )$$

wherein Rc represents the height of mounts and valleys; and Rsm represents the interval of mount and valley.

### Comparative Example 1

An alumina ceramic plate was prepared in the same manner as in the aforementioned examples except that no chemical etching was conducted. As a result, an alumina ceramic plate having a surface roughness Ra of 4.7 μm was obtained. The alumina ceramic plate thus obtained was then measured for adhesion force in the same manner as in the aforementioned examples. The results are set forth in Table 1.

TABLE 1

| | Temperature | | | | | |
|---|---|---|---|---|---|---|
| | of acid | | | | | Adhe- |
| | etching | Dipping | | | | sion |
| | solution | time | Pressure | Ra | Aspect | force |
| | (° C.) | (hr) | (MPa) | (μm) | ratio | (MPa) |
| Comparative | — | — | — | 4.7 | 0.207 | 4.2 |
| Example 1 | | | | | | |
| Example 1 | 170 | 4 | 0.8 | 4.6 | 0.349 | 8.2 |
| Example 2 | 200 | 4 | 1.6 | 7.2 | 0.425 | 12.1 |
| Example 3 | 200 | 8 | 1.6 | 10.4 | 0.524 | 13.6 |
| Example 4 | 200 | 12 | 1.6 | 14.7 | 0.921 | 8.8 |

As can be seen in the results of Table 1 above, when the surface of the alumina base material is subjected to chemical etching in addition to sandblasting, the resulting alumina base material exhibits a drastically enhanced adhesion force between the surface layer of the plasma resistant material and the base material. The relationship between the aspect ratio and the adhesion force of the roughened base material was studied. It can be thus confirmed that the greater the aspect ratio of the surface of the base material is, the greater is the adhesion force of the surface of the base material. This is probably because as the aspect ratio of the surface of the base material increases, the surface area of the base material increases, causing the rise of mechanical frictional force between the thermal spray layer and the base material leading to the rise of adhesion force.

### Examples 5 to 7

An alumina ceramic plate was prepared in the same manner as in Example 1 except that the etching conditions were as set forth in Table 2 below and annealing was effected at 1,700° C. for 3 hours. The alumina ceramic plate thus prepared was then measured for surface roughness, surface layer porosity, porous layer depth, aspect ratio and adhesion force. The measurement of adhesion force was performed in the same manner as in Example 1.

### Comparative Examples 2 to 4

An alumina ceramic plate was prepared in the same manner as in Example 6 except that no annealing was conducted (Comparative Example 2). Alumina ceramic plates were prepared in the same manner as in Examples 5 to 7 except that the etching conditions were as set forth in Table 2 below. These alumina ceramic plates were then measured for surface roughness, surface porosity, porous layer depth, aspect ratio and adhesion force.

TABLE 2

| | Temperature of | | | | | | | |
|---|---|---|---|---|---|---|---|---|
| | acid etching | Dipping | | | | | | Adhesion |
| | solution | time | Pressure | % | Depth | Ra | Aspect | force |
| | (° C.) | (hr) | (MPa) | Porosity | (μm) | (μm) | ratio | (MPa) |
| Comparative | 230 | 8 | 2.5 | 55 | 103.5 | 7.3 | 0.728 | 3.1 |
| Example 2 | | | | | | | | |
| Comparative | 200 | 4 | 1.6 | 14 | 7.0 | 1.6 | 0.102 | 3.5 |
| Example 3 | | | | | | | | |
| Comparative | 230 | 12 | 2.5 | 77 | 223.3 | 17.9 | 0.943 | 4.5 |
| Example 4 | | | | | | | | |
| Example 5 | 230 | 4 | 2.5 | 23 | 18.7 | 2.8 | 0.340 | 7.7 |
| Example 6 | 230 | 8 | 2.5 | 44 | 72.9 | 7.2 | 0.640 | 14.6 |
| Example 7 | 230 | 10 | 2.5 | 58 | 146.5 | 14.6 | 0.824 | 9.5 |

As can be seen in the results of Table 2 above, when the chemical etching conditions are optimized, a porous surface layer can be formed, making it possible to obtain an alumina ceramic plate having an enhanced adhesion force to the plasma resistant material layer.

[Brittle Material Base Material]

Another aspect of the present invention will be described.

In the present invention, a brittleness of the material to be used as a base material means a property which is defined that when given stress, the material can break in the form of crack or the like without plastic deformation. The lower the ambient temperature is, the greater the impact of stress is, the greater the content of inclusions or precipitates, or latent defects is, the more easily can occur brittle fracture of a material. In the present invention, as the brittle material there maybe used any material which can cause brittle fracture without causing ductile fracture which shows a remarkable anchoring effect.

Examples of the brittle material employable herein include sintering product of oxide-based ceramic such as alumina and zirconia, sintering product of non-oxide based ceramic such as aluminum nitride and silicon nitride, quartz material, and glass material. Specific examples of these brittle materials employable herein include alumina, yttrium aluminum garnet, aluminum nitride, yttria, zirconia, quartz glass, and borosilicate glass.

In the case where the aforementioned brittle material is a sintered ceramic, the grain size of the crystal constituting the sintered material is preferably from 2 to 70 μm. When the crystal grain size falls below the above defined range, it is disadvantageous in that the surface of the brittle material cannot be physically and chemically roughened sufficiently as necessary. On the contrary, when the crystal grain size exceeds the above defined range, it is disadvantageous in that strength of ceramic material itself tends to be deteriorated.

The method for forming a thermal spray coat of the present invention can be applied to materials other than brittle material. However, when the method for forming a thermal spray coat of the present invention is applied to other materials, the effect of enhancing the thin layer exfoliation preventing effect cannot be expected so much as in the case of brittle material. If applied to other materials, the process of the present invention complicates the working process and thus is uneconomical against the expectation.

[Roughening Method]

In the present invention, as the method for roughening the surface of the brittle material, there may be used a roughening method by chemical treatment rather than by physical force.

The aforementioned roughening method is accomplished by subjecting the aforementioned brittle material to liquid phase etching.

In the case where as the aforementioned brittle material there is used a sintered ceramics such as alumina, yttrium aluminum garnet, aluminum nitride, yttria and zirconia, the brittle material can be subjected to etching with an aqueous solution containing sulfuric acid in a concentration ranging from 18 to 50% by weight or phosphoric acid in an amount of 95% by weight or more to undergo roughening (see Japanese Patent Unexamined Publication JP-A-2003-171190).

When the concentration of the aqueous solution of sulfuric acid falls below 18% byweight or the concentration of phosphoric acid falls below 95% by weight, the etched amount of the brittle material is reduced, and prolonging the time required for chemical etching. On the contrary, when the concentration of the aqueous solution of sulfuric acid exceeds 50% by weight, it is made difficult to keep the concentration of the aqueous solution constant over an extended period of time.

The etching solution can be heated for increasing the etching speed. The upper limit of the heating temperature is predetermined such that the etching solution cannot undergo thermal decomposition. In the case where an aqueous solution of sulfuric acid is used, it can be pressed to accelerate the formation of unevenness. However, an aqueous solution of phosphoric acid is dangerous and thus cannot be pressed.

In the case where as the aforementioned brittle material there is used quartz glass. The quartz glass can be subjected to chemical frosting to undergo roughening. In the chemical frosting process, the surface of quartz glass is etched with a liquid treatment to undergo matting to obtain a frost surface such as a ground glass or an obscured glass. This chemical frosting is a known process as disclosed in Japanese Patent Unexamined Publication JP-A-2002-308649.

In the present embodiment, as the etching material to be used in chemical frosting there may be used a mixture of hydrogen fluoride, ammonium fluoride, acetic acid and water or a mixture of hydro fluoric acid, diammonium hydrogen phosphate and water.

The etching process may be performed at ordinary temperature or under heating. Alternatively, there action heat may be kept to keep substantial heated state.

The time during which the quartz glass is dipped in the etching solution varies with the temperature of the etching solution but is preferably from 10 to 90 minutes at a temperature of from 35° C. to 65° C. to perform effective etching. The quartz glass thus dipped can be washed with water to obtain roughened quartz glass.

When subjected to etching in the aforementioned manner, the brittle material can be provided with a roughened surface having Ra ranging from about 1 to 10 μm. When Ra falls below the above defined range, the thin layer formed by thermal spray coat onto the surface of the brittle material cannot be provided with sufficient adhesion strength and thus can be easily exfoliated. On the contrary, it is difficult for the aforementioned process to roughen the surface of the brittle material to Ra of 10 μm or more.

[Surface Protective Layer Material]

As the protective layer material to be formed on the surface of the brittle material, there is preferably used a plasma-resistant material. Particularly, an yttrium compound is preferably used. More particularly, preferred examples of such an yttrium, compound including solid solutions yttria, composite oxides containing yttria, and yttrium trifluoride. Specific examples of these yttrium compounds include yttria, zirconia-yttria solid solutions, rare earth oxide-yttria solid solutions, 3Y₂O₃.5Al₂O₃, YF₃, Y—Al—(O)—F, Y₂Zr₂O₇, Y₂O₃.Al₂O₃, and 2Y₂O₃.Al₂O₃.

The aforementioned protective layer material is preferably formed on the surface of the brittle material to a thickness of from 50 to 500 μm, more preferably from 100 to 300 μm. When the thickness of the protective layer material falls below the above defined range, it is disadvantageous in that the resulting member exhibits deteriorated durability. On the contrary, when the thickness of the protective layer material exceeds the above defined range, it is disadvantageous in that the resulting protective layer has residual stress that causes the exfoliation of the protective layer or the occurrence of crack in the protective layer.

[Method for the Formation of Protective Layer]

As the method for forming the protective layer on the surface of the brittle material there is preferably using thermal spray method. In some detail, any known thermal spray method such as flame spray, wire flame spray, rod flame spray, powder flame spray, high speed flame spray, explosion spray, arc spray, plasma spray, reduced pressure plasma spray, pressure plasma spray, submerged plasma spray, water-stabilized plasma spray, RF plasma spray, induction plasma spray, electro-magnetically-accelerated plasma spray, wire explosion spray, electro-thermally exploded powder spray, cold spray and laser spray can be adapted. Most desirable among these thermal spray methods is plasma spray because it is capable of sufficiently melting ceramics having high melting temperature.

### EXAMPLE

### Example 11

The surface of a light-transmitting alumina having a crystal grain size ranging from 10 to 20 μm was subjected to etching 25 wt-% aqueous solutions of sulfuric acid at a pressure of 2 MPa and a temperature of 230° C. for 8 hours to obtain a roughened surface having Ra of 5 μm. Onto the roughened surface of alumina was then plasma-spray coated yttrium aluminum ceramic to form a plasma resistant protective layer to a thickness of 200 μm.

In this manner, 10 samples were prepared. These samples were each then measured for adhesion force by a stud pull method. The measurements were then averaged. The results are set forth in Table 3.

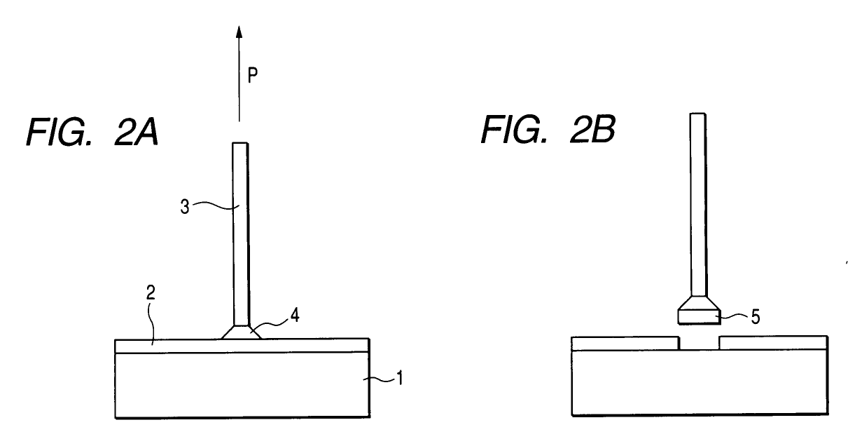

In the stud pull method, as shown in FIG. 2A, a stud pin having a bottom surface area of 5.7 mm² is bonded to the surface of a brittle material 1 having a protective layer 2 formed on the surface thereof with an epoxy resin 4. The force by which the protective layer 2 is exfoliated off the brittle material 1 when the stud pin 3 is then pulled upward (FIG. 2B) is then measured to determine the adhesion force. In FIG. 2B, the reference numeral 5 indicates the exfoliated portion of the protective layer 2.

### Example 12

The surface of alumina having a crystal grain size of 10 μm was subjected to etching 25 wt-% aqueous solutions of sulfuric acid at a pressure of 0.9 MPa and a temperature of 180° C. for 4 hours to obtain a roughened surface having Ra of 2 μm. Onto the roughened surface of alumina was then plasma sprayed yttria ceramic to form a plasma resistant protective layer to a thickness of 200 μm

In this manner, 10 samples were prepared. These samples were each then measured for adhesion force in the same manner as in Example 11. The measurements were then averaged. The results are also set forth in Table 3.

### Comparative Example 11

The surface of a light transmitting alumina having a crystal grain size of from 10 to 20 μm was subjected to sandblasting with a particulate alumina having an average grain size of 500 μm to obtain a roughened surface having Ra of 5 μm. On the roughened surface of alumina was then plasma sprayed yttria ceramic to form a plasma resistant protective layer to thickness of 200 μm.

In this manner, 10 samples were prepared. These samples were each then measured for adhesion force in the same manner as in Example 11. The measurements were then averaged. The results are also set forth in Table 3.

### Example 13

The surface of quartz was twice subjected to etching with an etching solution which is 50% hydrogen fluoride containing hydrogen phosphate and ammonium water at a weight ratio of 1:1 at 50° C. for 30 minutes to obtain a roughened surface having Ra of 5 μm. Onto the roughened surface of quartz was then plasma sprayed yttria ceramic to form a plasma resistant protective layer to a thickness of 200 μm.

In this manner, 10 samples were prepared. These samples were each then measured for adhesion force in the same manner as in Example 11. The measurements were then averaged. The results are also set forth in Table 3.

### Example 14

The surface of quartz was twice subjected to etching with an etching solution obtained by dissolving aqueous diammonium hydrogen phosphate in a 40% aqueous solution of hydrogen fluoride at 50° C. at a weight ratio of 1:1 for 30 minutes to obtain a roughened surface having Ra of 8 μm. Onto the roughened surface of quartz was then plasma sprayed yttria ceramic form a plasma resistant protective layer to a thickness of 200 μm.

In this manner, 10 samples were prepared. These samples were each then measured for adhesion force in the same manner as in example 11. The measurements were then averaged. The results are set forth in Table 3.

### Comparative Example 12

The surface of quartz was subjected to sandblasting with a particulate alumina having an average grain size of 500 μm to obtain a roughened surface having Ra of 5 μm. On the roughened surface of quartz was then plasma spray yttria ceramic to form a plasma resistant protective layer to thickness of 200 μm.

In this manner, 10 samples were prepared. These samples were each then measured for adhesion force in the same manner as in Example 11. The measurements were then averaged. The results are set forth in Table 3.

### Comparative Example 13

The surface of alumina was subjected to sand blasting with a particulate alumina having an average grain size of 500 μm to obtain a roughened surface having Ra of 5 μm. On the roughened surface of alumina was then plasma sprayed yttria ceramic to form a plasma resistant protective layer to thickness of 200 μm.

In this manner, 10 samples were prepared. These samples were each then measured for adhesion force in the same manner as in Example 11. The measurements were then averaged. The results are set forth in Table 3.

### Comparative Example 14

The surface of alumina having a crystal grain size of 5 μm was subjected to etching a 25 wt-% aqueous solution of sulfuric acid at a pressure of 0.6 MPa and a temperature of 160° C. for 4 hours to obtain a roughened surface having Ra of 0.5 μm. Onto the roughened surface of alumina was then plasma sprayed yttria ceramic to form a plasma resistant protective layer to thickness of 200 μm.

In this manner, 10 samples were prepared. These samples were each then measured for adhesion force in the same manner as in Example 11. The measurements were then averaged. The results are set forth in Table 3.

### Comparative Example 15

The surface of quartz was twice subjected to etching with an etching solution obtained by dissolving aqueous diammonium hydrogen phosphate in a 50% aqueous solution of hydrogen fluoride at 50° C. at a weight ratio of 1:1 for 1 hour to obtain a roughened surface having Ra of 0.5 μm. Onto the roughened surface of quartz was then plasma sprayed yttria ceramic to form a plasma resistant protective layer to thickness of 200 μm.

In this manner, 10 samples were prepared. These samples were each then measured for adhesion force in the same manner as in Example 11. The measurements were then averaged. The results are set forth in Table 3.

TABLE 3

| | | | | Adhesion | |
|---|---|---|---|---|---|
| | Base | Roughening | | force | |
| | material | method | Ra (μm) | (kgf/cm²) | Remarks |
| Example 11 | Alumina | Etching | 5 | 97.8 | |
| Example 12 | Alumina | Etching | 2 | 73.9 | |
| Comparative | Alumina | Sand- | 5 | 40.4 | |
| Example 11 | | blasting | | | |
| Example 13 | Quartz | Etching | 5 | 101.1 | |
| Example 14 | Quartz | Etching | 8 | 114.7 | |
| Comparative | Quartz | Sand- | 5 | 35.6 | Base |
| Example 12 | | blasting | | | material |
| | | | | | broken |
| Comparative | Alumina | Sand- | 10 | 128.2 | |
| Example 13 | | blasting | | | |
| Comparative | Alumina | Etching | 0.5 | — | Layer was |
| Example 14 | | | | | exfoliated |
| Comparative | Quartz | Etching | 0.5 | — | Layer was |
| Example 15 | | | | | exfoliated |

As can be seen in the results of Table 1 above clearly, Comparative Example 11, in which the surface of a brittle material made of sintered ceramic is subjected to physical sandblasting, exhibits a lower adhesion force than the embodiments of the present invention. Comparative Example 12, in which quartz is subjected to sandblasting, underwent crack in its base material and showed break in its base material during the adhesion test.

Comparative Examples 4 and 5, in which a brittle material is subjected to chemical etching to have a roughness of 0.5, did not allow sufficient adhesion force of thermal spray layer and underwent exfoliation of thermal spray layer during the preparation of samples.

When there occurs microcracks on the surface of the base material at an interface defined between the base material and the thermal spray layer, these microcracks act as starting points of causing exfoliation of the thermal spray layer. In other words, exfoliation occurs due to tension which is lower than the adhesion strength that can be expected from interface formation.

In the present invention, not any microcracks occur on the interface, causing no exfoliation of the thermal spray layer as the explained exfoliation model. As a result, the adhesion strength between the thermal spray layer and the base material is drastically enhanced.

According to the afore-mentioned present invention, the plasma resistant member having high adhesion strength between the alumina base material and the surface layer of a plasma resistant material formed thereon by thermal spray coating can be achieved.

According to the present invention, due to the chemical etching of the surface of the base brittle material, it can prevent an occurrence of microcracks and form a roughened surface having deeper grooves. Accordingly, the adhesion strength between the thermal spray coat formed on surface and the brittle base material is improved and hence, it can form a thermal spray coat which occurs little generation of exfoliation of the thermal spray coat and dusts.

While the foregoing has been described in connection with the exemplary, non-limiting embodiment of the present invention, it will be obvious to those skilled in the art that various changes and modification may be made therein without departing from the present invention, and it is aimed, therefore, to cover in the appended claim all such changes and modifications as fall within the true spirit and scope of the present invention.

What is claimed is:

1. A plasma resistant member, comprising:
a base material made of alumina; and
a thermal spray layer made of Y₂O₃ or YAG formed on a surface of the base material,
wherein at least a part of the surface of the base material on which the thermal spray layer is formed has a surface roughness Ra ranging from 5 μm to 15 μm.

2. A plasma resistant member, comprising:
a base material made of alumina; and
a thermal spray layer made of Y₂O₃or YAG formed on a surface layer of the base material,
wherein at least a part of the surface layer of the base material is a porous layer having a porosity of 20% or more and 60% or less with a depth thereof being 10 μm or more and 100 μm or less.

3. The plasma resistant member as set forth in claim 2, wherein at least the part of the surface layer on which the thermal spray layer is formed has a surface roughness Ra ranging from 2 μm to 10 μm.

4. The plasma resistant member as set forth in claim 1, wherein the thermal spray layer comprises Y₂O₃ including Si ranging from 100 ppm to 1000 ppm.

5. The plasma resistant member as set forth in claim 2, wherein the thermal spray layer comprises Y₂O₃ including Si ranging from 100 ppm to 1000 ppm.

6. The plasma resistant member as set forth in claim 1, wherein at least a surface layer of the base material on which the thermal spray layer is formed has an aspect ratio ranging from 0.3 to 1.0.

7. The plasma resistant member as set forth in claim 2, wherein at least the surface layer of the base material on which the thermal spray layer is formed has an aspect ratio ranging from 0.3 to 1.0.

8. A method for manufacturing a plasma resistant member, comprising steps of:
performing a chemical etching on a surface of a base material made of alumina, and performing thermal spray Y₂O₃ or YAG onto the surface of the base material to form a plasma resistant layer.

9. The method for manufacturing the plasma resistant member as set forth in claim 8, wherein the chemical etching is performed with an acid etching solution at a temperature ranging from 160° C. to 240° C. in a pressure ranging from 0.6 MPa to 3.3 MPa for 3 hours or more and 10 hours or less.

10. The method for manufacturing the plasma resistant member as set forth in claim 8, wherein the chemical etching is performed with an acid etching solution at a temperature ranging from 180° C. to 240° C. in a pressure ranging from 1.0 MPa to 3.3 MPa for 3 hours or more and 10 hours or less.

11. The method for manufacturing the plasma resistant member as set forth in claim 9, further comprising a step of:
annealing the base material at a temperature ranging from 1,500° C. to 1,800° C. in an atmosphere for 4 hours or more and 8 hours or less after performing the chemical etching.

12. The method for manufacturing the plasma resistant member as set forth in claim 11, wherein at least a surface layer of the base material on which the thermal spray is performed has an aspect ratio ranging from 0.3 to 1.0 after annealing.

13. The method for manufacturing the plasma resistant member as set forth in claim 8, wherein the plasma resistant layer is made of the Y₂O₃, the Y₂O₃ contains Si in an amount of 100 ppm or more and 1000 ppm or less.

14. The method for manufacturing the plasma resistant member as set forth in claim 8, wherein the surface of the base material has a surface roughness Ra ranging from 5 μm to 15 μm after performing the chemical etching.

15. The method for manufacturing the plasma resistant member as set forth in claim 6, wherein a surface layer of the base material is a porous layer having a porosity ratio of 20% or more and 60% or less, and
a depth of the porous layer is 10 μm or more and 100 μm or less.

16. A method for forming a thermal spray coat, comprising steps of:
chemically roughening a surface of a brittle material; and
forming the thermal spray coat by performing thermal spray on the surface of the brittle material,
wherein the roughened surface of the brittle material has a surface roughness Ra of 1 μm or more and 10 or less.

17. The method for forming the thermal spray layer as set forth in claim 16, wherein the brittle material is a sintered ceramic material containing crystals having a grain size of 2 μm or more and 70 μm or less, and
the chemical roughening is performed with an acid etching solution.

18. The method for forming the thermal spray layer as set forth in claim 16, wherein the brittle material is quartz, and
the chemical roughening is performed by chemical frosting treatment.

19. A method for manufacturing a composite material comprising a brittle material and a protective coat formed on a surface of the brittle material, comprises steps of;
chemically roughening the surface of the brittle material to obtain a surface roughness thereof ranging from 1 μm to 10 μm; and
performing thermal spray on the surface of the brittle material to form the protective coat.
